(19) United States
(12) Patent Application Publication
(10) Pub. No.: US 2021/0090945 A1
(43) Pub. Date: Mar. 25, 2021

(54) SYSTEM AND METHOD FOR INTERCONNECTION

(71) Applicant: Vathys, Inc., Portland, OR (US)

(72) Inventor: Tapabrata Ghosh, Portland, OR (US)

(21) Appl. No.: 16/576,482

(22) Filed: Sep. 19, 2019

(51) Int. Cl. H01L 21/768; H01L 25/065; H01L 21/50; H01L 23/538

(52) U.S. Cl. CPC H01L 21/76838; H01L 25/0655; H01L 23/5386; H01L 23/5381; H01L 23/5385; H01L 21/50

(57) ABSTRACT

Multichip technology, where several discrete chips are assembled or are fabricated on a single substrate can offer many advantages, including better scaling and better yield. However, existing methods of connecting the individual chips on a substrate, leaves these devices operating at much slower rates than their individual chips are capable of operating. Disclosed are systems and methods for fast interconnect structures between chips in a multi die setup, where density, bandwidth, power consumption and other interconnect operating parameters are improved.

### BACKGROUND

### Field

This invention relates generally to the field of multi-die computing systems and more particularly to interconnect structures.

### Description of the Related Art

Advances in chip design have focused on increasing performance of on-chip operations in a single chip integrating multiple computing functionality. Recently, advantages of combining multiple discrete chips on a single substrate to build more complex computing systems have become more apparent. Multichip designs allow for better yield and easier design and manufacturing. if one chip experiences a generational upgrade, the other chips are unaffected and can be used as they have been. Single chip designs, on the other hand, need to be overhauled entirely if a single component is upgraded. Similarly, manufacturing yield in single die devices can be lower than multichip setups. A single component failure in a single-die chip, can render the entire chip defective. In multi-die, multichip systems, a defective module can be replaced and the functionality of the entirety of the system can be restored.

Nonetheless, the adoption and wide-spread use of the multi-die, multichip systems have been slow because the current interconnect technology, used to connect multiple chips in such devices remains slower than the interconnect technology used in single chips. On-chip communication speed and bandwidth are still several orders of magnitude greater than speed and bandwidth of inter-chip communication, Conversely, multi-die, multichip systems can be built with very capable and performant individual chips, but the slow inter-chip communication causes these devices to operate much slower than the speed of their individual chips might suggest. This is, in part, due to the structure and design of interconnect technology used to connect the dies on a substrate. Manufacturing limitations, such as those dictated by traditional optical lithography, along with other factors, have contributed to the slow interconnect technology in modern multichip devices. Consequently, there is a need for improved interconnect technology that would allow the adoption and usage of modern multichip devices.

### SUMMARY

In one aspect, a method of manufacturing a multichip system is disclosed. The method includes: fabricating and/or placing a plurality of chiplets on a substrate, each chiplet comprising a plurality of connection points; and fabricating one or more interconnect structures between two or more of the plurality of the connection points of the chiplets, communicatively coupling two or more chiplets, wherein fabricating an interconnect structure comprises: determining a source connection point; determining a destination connection point; generating a digital path between the source connection point and the destination connection point; and building an interconnect structure along the digital path.

In one embodiment, the fabricating and/or placing of the plurality of the chiplets on the substrate is performed before fabricating the one or more interconnect structures.

In another embodiment, building the interconnect structure is performed by one or more of: nonlinear optical lithography, photon-induced lithography, focused electron beam induced deposition (FEBID), focused ion beam, atomic optics, direct ink writing, electrohydrodynamic printing, local electrophoretic reduction, Meniscus-confined electroplating, electroplating of locally dispensed ions in liquid, laser-induced photoreduction, laser-assisted chemical vapor deposition (CVD), stimulated emission depletion (STED) lithography, laser induced forward transfer, and cryogenic FEBID or ion beam induced deposition.

In one embodiment, the nonlinear optical lithography comprises two or multi-photon polymerization lithography.

In another embodiment, the two or multi-photon polymerization lithography comprises polymerizing a photoresist material comprising nano metal particles.

In one embodiment, the method further includes coating the interconnect structure at least partially with a metal layer.

In one embodiment, the coating comprises one or more of: electroless plating, electroplating, chemical vapor deposition (CVD), molecular beam epitaxy (MBE), atomic layer deposition (ALD), and physical vapor deposition (PVD).

In some embodiments, the one or more chiplets are misaligned in any direction in the three-dimensional space.

In one embodiment, the substrate contains topographical variations causing a misalignment in z-axis direction.

In some embodiments, the interconnect structures are driven by one or more of alternating current (AC)-coupled driving, capacitively-coupled AC interconnection, inductive coupling, galvanic connections, direct current (DC) or resistive connections, and serializer/de-serializer (SerDes).

In one embodiment, building the interconnect structure comprises focusing a light beam, an electron beam, an ion beam, and/or an atom beam along the digital path.

In another embodiment, building the interconnect structure comprises depositing electrically conductive material along the digital path.

In some embodiments, building the interconnect structure comprises coating the interconnect structure with electrically conductive material.

In another aspect, a multichip module system is disclosed. The system includes: a plurality of chiplets on a substrate, each chiplet comprising a plurality of connection points; and one or more interconnect structures fabricated between two or more of the plurality of the connection points of the chiplets, communicatively coupling the two or more chiplets, wherein the interconnect structures are fabricated in photoresist material, and/or are deposited between the connection points by focusing a light beam, an electron beam, an ion beam, and/or an atom beam along a digital path indicating electrical connection between the connection points.

In one embodiment, the chiplets are placed on the substrate before the interconnect structures are fabricated between the two or more of the plurality of the connection points.

In another embodiment, the interconnect structures are fabricated by one or more of: nonlinear optical lithography, photon-induced lithography, focused electron beam induced deposition (FEBID), focused ion beam, atomic optics, direct ink writing, electrohydrodynamic printing, local electrophoretic reduction, Meniscus-confined electroplating, electroplating of locally dispensed ions in liquid, laser-induced photoreduction, laser-assisted chemical vapor deposition (CVD), stimulated emission depletion (STED) lithography, laser induced forward transfer, and cryogenic FEBID or ion beam induced deposition.

In some embodiments, nonlinear optical lithography comprises two or multi-photon polymerization lithography.

In one embodiment, the two or multi-photon polymerization lithography comprises polymerizing a photoresist material comprising nano metal particles.

In another embodiment, the interconnect structures are coated at least partially with a metal layer, wherein the coating comprises one or more of: electroless plating, electroplating, chemical vapor deposition (CVD), molecular beam epitaxy (MBE), atomic layer deposition (ALD), and physical vapor deposition (PVD).

In one embodiment, the interconnect structures are driven by one or more of alternating current (AC)-coupled driving, capacitively-coupled AC interconnection, inductive coupling, galvanic connections, direct current (DC) or resistive connections, and serializer/de-serializer (SerDes).

### BRIEF DESCRIPTION OF THE DRAWINGS

These drawings and the associated description herein are provided to illustrate specific embodiments of the invention and are not intended to be limiting.

FIG. 1 illustrates a diagram of a multichip module (MCM) system.

FIG. 2 illustrates a diagram of manufacturing an MCM device according to an embodiment.

FIG. 3 illustrates a diagram of chiplets of an MCM device, where the chiplets are in good alignment.

FIG. 4 illustrates a diagram of chiplets of an MCM device, where the chiplets are in misalignment.

FIG. 5 illustrates a diagram of chiplets of an MCM device on a substrate, with no topographical variation.

FIG. 6 illustrates a diagram of chiplets of an MCM device on a substrate, where topographical variations on the substrate is causing a misalignment between the chiplets.

FIG. 7 illustrates a two-photon polymerization (TPP) system that can be used to manufacture interconnect structures in an MCM device.

FIG. 8 illustrates a method of manufacturing an MCM device according to an embodiment.

FIG. 9 illustrates a multi-substrate MCM system 66, where a side-by-side arrangement of substrates are used.

FIG. 10 illustrates an alternatively-arranged multi-substrate MCM system.

FIG. 11 illustrates a diagram of manufacturing interconnect structures 26 in a multi-substrate MCM system, with a chamber smaller than the substrates.

### DETAILED DESCRIPTION

The following detailed description of certain embodiments presents various descriptions of specific embodiments of the invention. However, the invention can be embodied in a multitude of different ways as defined and covered by the claims. In this description, reference is made to the drawings where like reference numerals may indicate identical or functionally similar elements.

Unless defined otherwise, all terms used herein have the same meaning as are commonly understood by one of skill in the art to which this invention belongs. All patents, patent applications and publications referred to throughout the disclosure herein are incorporated by reference in their entirety. In the event that there is a plurality of definitions for a term herein, those in this section prevail. When the terms “one”, “a” or “an” are used in the disclosure, they mean “at least one” or “one or more”, unless otherwise indicated.

Monolithic and Heterogenous Integrated Circuits

The progress of computing hardware has focused on increasing performance and efficiency of the computing systems. Various proposals and architectures have emerged to provide more efficient hardware. This is needed, as we continue to experience an increase in demand for compute resources for modern workloads. Modern computational workloads, such as artificial intelligence (AI) and related computational workloads, can and do make use of the existing hardware, but can also use more efficient yet unavailable hardware.

So far, monolithic integrated circuits (ICs), where many or all computing functionality are integrated into a single die have dominated the design of computer architectures. However, increasingly, multi-die, multiple-chip module (MCM) technology, where several discrete integrated circuits are integrated into a substrate has shown greater promise and compatibility with the way IC design and manufacturing has evolved. In MCM, computer systems are manufactured by placing chiplets in serial or parallel connections to achieve computing functionality. Multi-die computing systems, such as MCMs are easier to manufacture, upgrade and assemble together to customize computing functionality.

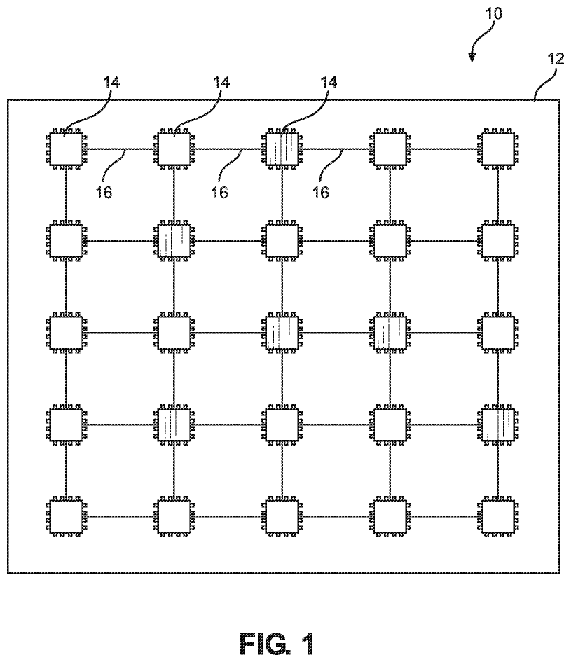

FIG. 1 illustrates an MCM 10. Chiplets 14 are connected using interconnects 16. The chiplets 14 can be identical, similar or can implement different compute functions. Example chiplets 14 include: microprocessors, memory modules, field programmable gate arrays (FPGAs), Analog to digital converters (ADCs), digital to analog converters (DACs), digital logic, three-dimensional ICs, three-dimensional memory stacks, graphics processing units (GPUs), and any other analog, digital or hybrid chips. Each chiplet may be manufactured on a single die or a combination of multiple dies. It may be prefabricated and installed on the substrate 12, or it can be fabricated on the substrate 12. The substrate 12 may be a variety of material, including a silicon substrate, organic substrate or various polymers. In one embodiment, the substrate 12 can be made of flexible material. Chiplets 14 can be connected via the interconnects 16 to one another. The structure of the MCM 10 can be applied efficiently to many artificial intelligence (AI) tasks, where the serialization and parallelization of the chiplets can follow the computational direction of the AI tasks, or otherwise be customized to perform AI tasks. However, the MCM 10 is applicable to any computing tasks and can offer multiple advantages, in terms of design efficiency, cost and yield, compared to monolithic IC systems.

The adoption and widespread use of non-monolithic computing systems, such as MCM 10 has been slow due to limitations in achieving desirable speed and efficiency of transfer of data between chiplets 14 via the interconnects 16. Currently, the energy consumption and delay of signaling between chiplets 14 via interconnects 16 can be several orders of magnitude larger than those of on-chip energy consumption and delay that may be observed on monolithic designs. Some approaches have relied on special signaling techniques to address this issue, nonetheless, the power consumption and delays in multi-die devices can be larger than those of monolithic devices. Furthermore, the way multichip devices and interconnects 16 are manufactured, the interconnects 16 can be relatively large, reducing the interconnect 16 density per unit of area and reducing bandwidth. As a result, MCM devices 10 can suffer from low performance, regardless of the efficiency and high performance of individual chiplets 14. Some manufacturers have even abandoned multichip efforts in favor of other integration techniques, such as wafer-scale-integration (WSI) to avoid the interconnect inefficiency, experienced in current technology (WSI aims to build a computing system and its sub-parts on one silicon wafer, as one integrated giant chip).

Current methods of manufacturing the MCM 10 can start by laying a lattice of interconnects 16 on a substrate 12, using various fabrication techniques, and then placing the chiplets 14 on various locations on the interconnects 16, based on their functionality and required connectivity. To avoid misalignment of the chiplets 14 and their interconnects 16, the interconnects 16 are made with a large margin to accommodate potential manufacturing variances and minimize misalignment. Misalignment between chiplets 14 or chiplets 14 and interconnects 16 can render the MCM 10 defective. At the same time, the relatively large size of the substrate 12 in the MCM 10 and similar systems, can create a high probability of occurrence of misalignment, when conventional lithography techniques are used to create chiplets 14 and/or the interconnects 16. Furthermore, manufacturing the MCM 10 by using aggressive conventional lithography techniques can substantially reduce yield and raise the cost of manufacturing of the MCM 10 devices. As a result, the interconnects 16 are often manufactured in large sizes and low interconnect density. Such limitations, not only appear in traditional organic substrate-based MCMs, but also appear in more advanced MCMs which use interposer-type substrates, such as those based on silicon, Conventional MCMs can also be limited in how many chiplets 14 they can incorporate in a module. A large MCM device might be able to fit four full reticle-sized dies in a module (as an example, a large interposer is approximately 2500 square millimeters in area).

The MCM 10 can be manufactured according to the techniques described herein to avoid misalignment issues described above and to impart other benefits. In some embodiments, the chiplets 14 can be placed on the substrate 12 or be fabricated on substrate 12. A variety of techniques can then be used to build the interconnects 16. In other words, the interconnects 16 can be built after the chiplets 14 have been laid out on the substrate 12.

Improved Multichip Device

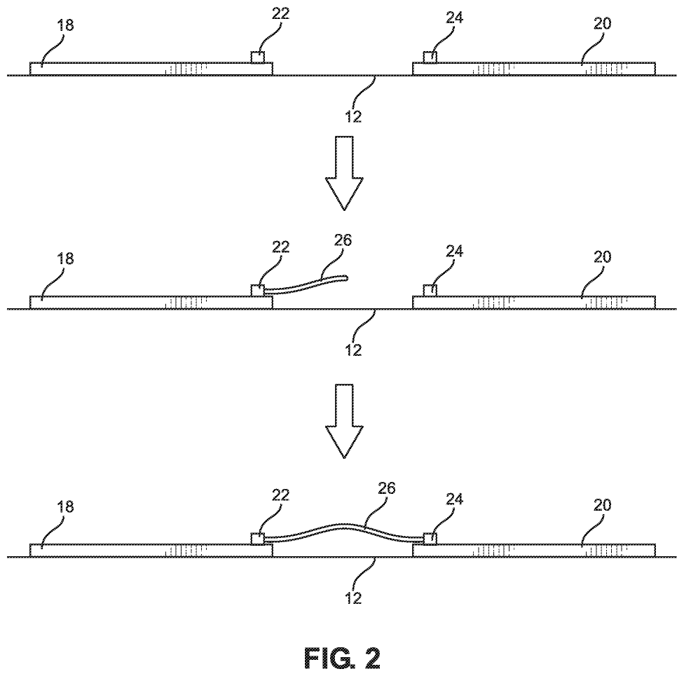

FIG. 2 illustrates a diagram of manufacturing an MCM device according to an embodiment. Chiplets 18 and 20 are laid out on the substrate 12, based on a variety of considerations, such as their functionality, and or input/output ports. For example, chiplet 18 may be a microprocessor IC and chiplet 20 may be a memory stack. Chiplets 18 and 20 can be adjacent or can be some distance away from one another, where one or more other chiplets may be present between them. For ease of illustration, other chiplets that may be present are not shown. The chiplets 18 and 20 may have connection points 22 and 24, respectively, that can be used to electrically connect and provide communication between the two chiplets 18 and 20. For ease of illustration, only two connection points 22 and 24 are shown. However, a plurality of connection points 22 and 24 to and from the chiplets 18 and 20 and to and from other chiplets are also possible.

A variety of manufacturing techniques can be used to build interconnect structures 26 to connect the connection points 22 and 24 between chiplets 18 and 20. These manufacturing techniques can include, additive manufacturing techniques to build interconnect structures connecting various connection points between chiplets. Example manufacturing techniques, which can be used to build the interconnect structure 26 include nonlinear optical lithography (e.g. two or multi-photon polymerization), photon-induced lithography, focused charged particle beams such as focused electron beam induced deposition (FEBID), focused ion beam, atomic optics, direct ink writing, electrohydrodynamic printing, local electrophoretic reduction, Meniscus-confined electroplating, electroplating of locally dispensed ions in liquid, laser-induced photoreduction, laser-assisted chemical vapor deposition (CVD), stimulated emission depletion (STED) lithography, laser induced forward transfer, and cryogenic FEBID (or ion beam induced deposition). Referencing FIG. 1, these techniques can be used alone, or in combination to build the interconnect structures 26 based on the layout and design of the MCM 10. In some embodiments, the techniques used to fabricate the interconnects 26 are capable of fabricating three-dimensional shapes in and between connection points on various chiplets 14 and connection points therein. In some embodiments, both an underlying interconnect lattice made up of interconnects 16 and a plurality of overlay interconnect structures 26 can be used in the MCM 10. In other embodiments, the under-chip interconnect lattice can be excluded and only overlay interconnect structures 26 used.

Interconnect Structures Built with Nonlinear Lithography

In one embodiment, the interconnect structures 26 can be built using nonlinear optical lithography, for example, two or multi-photon polymerization can be used. In one embodiment, the photoresist material used in nonlinear optical lithography can be a photoresist material containing nano metal particles, such as gold, silver copper, aluminum or other metal particles, in order to create an electrically conductive connection. In another embodiment, when polymerization is used, a post processing step can be used to create an electrically conductive interconnect structure 26. Examples include, electroless plating, electroplating, chemical vapor deposition (CVD), molecular beam epitaxy (MBE), atomic layer deposition (ALD), physical vapor deposition (PVD), or a combination of these techniques. In another embodiment, nonlinear optical lithography can be used to build non-metallic, but conductive interconnect structures 26. An example includes, carbon nanotubes (CNTs).

In one embodiment, two-photon polymerization can be used to build the interconnect structures 26, by using tools obtained from Nanoscribe® of Karlsruhe, Germany (Phone No. +49 721 981 980 0).

Connection points 22, 24 and interconnect structures 26 can be driven by a variety of techniques, including alternating current (AC)-coupled driving or capacitively-coupled AC interconnection. Other interconnect driving methods, which can be used, include inductive coupling, galvanic connections, direct current (DC) or resistive connections or some combination of the disclosed driving techniques. In another embodiment, serializer/de-serializer (SerDes) methods can be used, Although, it is possible to instead create more interconnects 26, as needed, and avoid having to use SerDes methods to save on energy and area that would otherwise be used by SerDes.

Using the above described techniques, the interconnect structure 26 can be made electrically conductive in some parts and can be made electrically insulated in other parts. In some embodiments, the interconnect structure 26 can be a multilayered structure, where some layers are electrically conductive and provide communication between the chiplets 18 and 20 via connection points 22 and 24, respectively, and some layers are electrically insulating. The insulating layers of the interconnect structure 26 can electrically isolate the signal between the chiplets 18 and 24 and prevent or reduce leakage electrical current to other components. Other layers of the interconnect structure 26 may serve as mechanical support structures to allow for other chiplets or interconnect structures 26 to be built above the substrate 12 and the chiplets 18 and 20.

Advantages of the Interconnect Structure 26

The described systems and methods solve many challenges that exist in IC packaging and interconnect technology. For example, the described techniques of manufacturing the interconnect structure 26 are capable of achieving smaller-size (nano-scale) interconnects. They can increase the density or connections per unit of area, compared to traditional underlay interconnect lattice structures. Higher bandwidth and lower power consumption can also be achieved by utilizing the interconnect structures 26 built using the described techniques. For example, using two-photon lithography (e.g., with tools available from Nanoscribe®), interconnect density resolution of approximately 100 nanometers can be achieved, which is significantly denser than connections available in MCMs with underlay interconnect structures, or in MCMs with interposer modules. Similarly, the interconnect density achievable by the interconnect structures 26 and the described techniques can be denser than connections available in WSI systems.

The interconnect density of an MCM 10 using the interconnect structure 26 can further be increased by using techniques, such as scattering lithography and nonlinear scattering lithography, or FEBID techniques. Using these techniques, the density of the interconnect structures 26 can be higher than those achievable on lower metal on-chip wires.

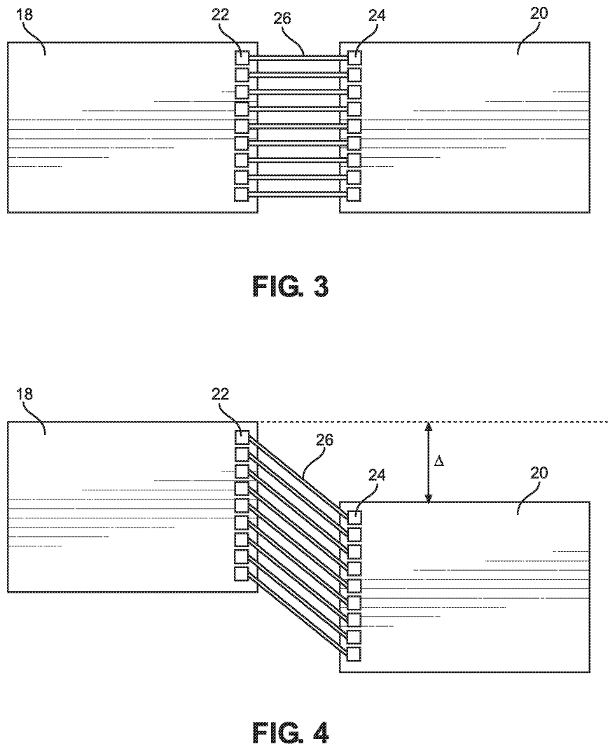

Furthermore, the interconnect structures 26 and the described techniques of building them solve the misalignment challenges that the MCM 10 or other similar devices face. Conventionally, when misalignment in placement and/or manufacturing of the chiplets 14 and the underlay interconnect lattice structure happens, connections to and from some chiplets are compromised and the MCM 10 may be rendered defective. As a result, the sizing of the underlay lattice structure, and associated components, such as wires, pads, etc. are chosen to be large to reduce or eliminate misalignment. However, by placing, assembling and/or fabricating the chiplets 14, first, and building the overlay interconnect structures 26, second, misalignment can be handled without compromising connections and communications to and from the misaligned chips. FIG. 3 illustrates a diagram of chiplets 18 and 20 in good alignment, where the chiplets 18 and 20 have no offset in vertical, horizontal or angular position, relative to one another. Their respective connection points 22 and 24 are aligned on a straight line parallel to one or more edges of the chiplets 18 and 20. Interconnect structures 2.6 can be used to connect the connection points 22 and 24. FIG. 4, by contrast, illustrates a diagram of the chiplets 18 and 20 in misalignment, where the chiplets 18 and 20 are offset by a misalignment distance, delta, in the horizontal direction. Connection points 22 and 24 are on lines that intersect the non-connection edges of the chiplets 18 and 20. Nonetheless, the interconnect structures 26, using the above-described techniques, can be manufactured to connect the connection points 22 and 24, without compromising connection or connectivity between the chiplets 18 and 20. In other words, the interconnect structures 26 are built after the misalignment is known, or can be observed. The described methods of building the interconnect structures 26, therefore, can be deployed based on the observed locations of the connection points 22 and 24, relative to one another. As will be described, position information of the chiplets 18 and 20 and the connection points 22 and 24 (and any misalignment information) can be used in generating a connectivity map 31 where the described methods of building interconnect structures 26 can be deployed to build the interconnect structures 26, as desired.

While the example shown in FIG. 4 illustrates a misalignment comprising an offset in the horizontal direction, the described systems and methods of interconnect structure 26 can be used to build connection and communication interfaces between chiplets 18, 20 having other types of misalignments relative to one another, such as misalignment in the horizontal direction, in the angular direction or any combination of misalignment types. Misalignment can occur from a variety of sources and steps in the manufacturing of a multi-die system, such as fabrication or placement, soldering, etc. Nonetheless, if misalignment occurs, the interconnect structures 26 can be built, based on where the chiplets 18 and 20, and their respective connection points 22 and 24, are located. Thus, the described systems and methods of interconnect can be used to provide connection and connectivity between misaligned chiplets and improve yield.

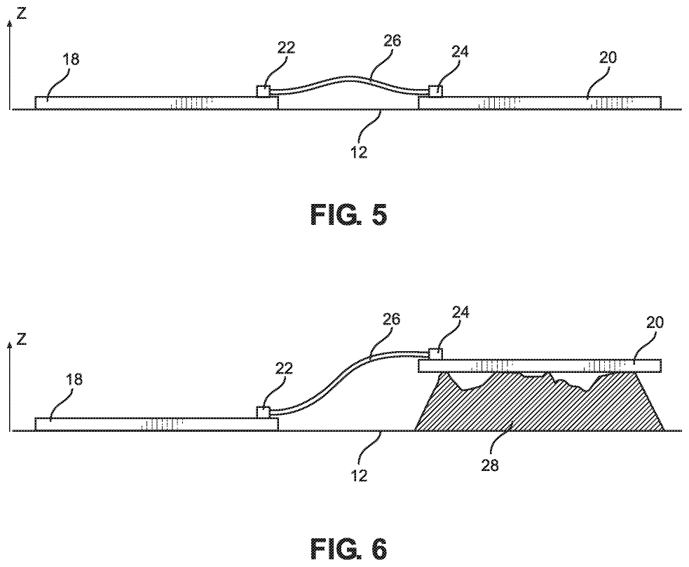

Another advantage of the disclosed systems and methods of interconnect structures 26 is that it addresses topographical variations that exist and/or can occur during manufacturing of MCM 10 or similar devices. For example, no substrate 12 is perfectly flat and topographical variations on the substrate 12 can cause the chiplets 18 and 20 to be misaligned along the z-axis. Topographical variations can be particularly problematic in large substrates, where it is more difficult to control for and reduce the number of topographical variations. FIG. 5 illustrates a substrate 12, and chiplets 18 and 20, where no topographical variation has caused a misalignment in the z-axis direction. FIG. 6 illustrates a diagram of an example topographical variation 28 causing a misalignment in the z-axis direction between the chiplets 18 and 20. Nonetheless, if such misalignments occur, the disclosed systems and methods of interconnect structures 26 can be applied in a manner that adapts to the topographical variations that may be present between chiplets 18 and 20.

Another advantage of the disclosed systems and methods of interconnect structure 26 is that, they are scalable to an arbitrary degree, compared to traditional MCM and WSI manufacturing techniques using standard lithographical techniques. The size of an MCM or WSI computing system manufactured using traditional lithography techniques is limited by lithographical limits of the equipment used, such as maximum wafer size, reticle size, or other limiting factors. The disclosed systems and methods of interconnect structure 26, however, are not limited by standard lithographic constraints. For example, the substrate size or number of chiplets 18 and 20 are not limited, by lithographical constraints. As an example, a roll of copper or other substrate material can be placed in a manufacturing chamber of a size that can accommodate the substrate, and the disclosed interconnect structures 26 can be used to connect a plurality of chiplets 18 and 20 to build massive computing systems of nearly any size. The size of the manufacturing chamber can be determined by the chosen method and type of manufacturing of the interconnect structure 26.

Conventional methods of interconnects can introduce low scalability because their scalability can be compromised, as new scaling generations are introduced. For example, many methods that rely on an underlay interconnect lattice structure may not be scalable when new generation scaling introduces chiplets of different sizes or different connection points. By contrast, the disclosed systems and methods do not encounter a scalability challenge as new scaling generations are introduced. The described methods of manufacturing of the interconnect structure 26 can build these interconnects in the nanometer ranges, based on where connections are needed. Interconnect structures 26 in the 100 nanometer or smaller sizes can be built, using the above-described techniques, to connect the next-generation chiplets 18 and 20.

A variety of material can be used for substrate 12, including flexible substrate material. The interconnect structure 26 can be made with flexible material to complement and/or accommodate the flexibility of the flexible substrate materials used to build substrate 12. The interconnect structures 26 can be used to build versatile, low cost, low loss interconnect fabrics. In some embodiments, the interconnect structure 26 can be built as a three-dimensional (3D) interconnect structure.

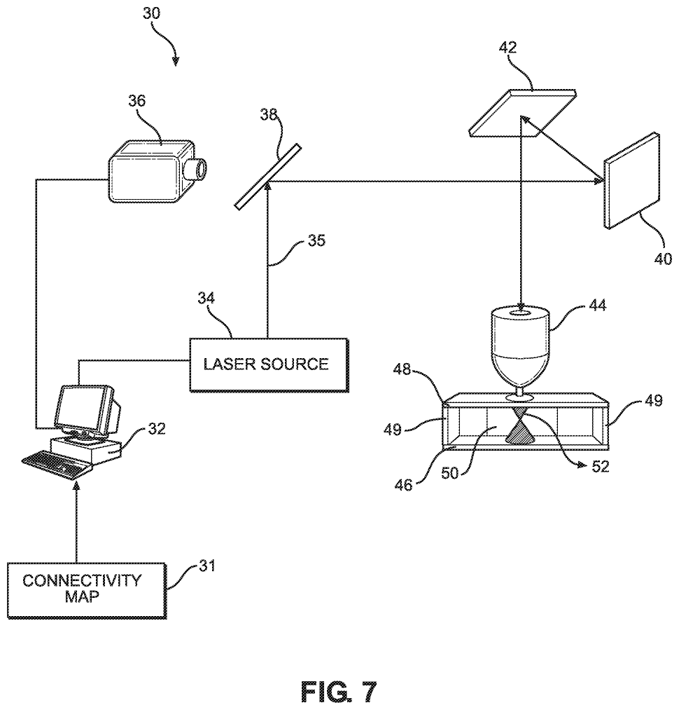

FIG. 7 illustrates a two-photon polymerization (TPP) system 30 that can be used to manufacture the interconnect structures 26. A computer 32 can control the operations of the TPP system 30, using a camera 36 to monitor the status of the process of two-photon polymerization. The camera 36 can be a charge coupled device (CCD) or other cameras with high resolution capability. The computer 32 can include one or more processors, random access memory (RAM) and non-volatile, long-term storage, such as hard disk drive (HDD) or flash disk drive (FDD). The computer 32 can also have wireless or wired connections to the other parts of the TPP system 30 and/or other computers, or cloud computing facilities via local networks or the internet. In one embodiment, a connectivity map 31 of the chiplets in an MCM 10 can be stored in the computer 32, based on which the computer 32 can build interconnect structures 26 in the MCM 10. The connection map 31 can include the specifications and locations of the interconnect structures 26, including any misalignment information. In some embodiments, the computer 32 can be configured to built interconnect structures 2.6 based on observations, for example, from an electron microscope to place those interconnect structures 26, between desired connection points.

The computer 32 can control a laser source 34, a series of motorized mirrors 38, 40 and 42, a high-power objective lens 44, and translational stage (glass substrates 48, 46 and spacers 49). The laser source 34 can generate laser 35 which can be focused anywhere in the volume of a photoresist material 50 after traveling through the motorized mirrors 38, 40 and 42 and the objective lens 44. The laser waist 52 of the laser beam 35 can cause polymerization of the photoresist material 50 to write any two-dimensional (2D) or three-dimensional (3D) interconnect structure 26 within the volume of the photoresist material 50. Referring to FIGS. 2-6, the computer 32 can adjust the position of the laser waist 52 to build interconnect structures 26 on connection points 22 and 24 depending on the connectivity map 31 between chiplets 18 and 20.

To manufacture nanometer-scaled interconnect structures 26, the laser source 34 can be a femtosecond laser. The computer 32 can move the motorized mirrors 38, 40 and 42, the objective lens 44, and/or the translational stage in order to three-dimensionally position the laser waist 52 within the photoresist material 50 according to the connectivity map 31 to create the interconnect structures 26 in the photoresist material 50.

In one embodiment, the photoresist material 50 can be a negative-tone photoresist material, where polymerization due to the laser waist 52 results from cross-linking of polymer-chains. The unexposed areas of the photoresist material 50 can be washed away or etched away with a solvent to leave the exposed areas as interconnect structures 26.

In another embodiment, the photoresist material 50 can be a positive-tone photoresist material, where polymerization due to the laser waist 50 in exposed areas results from chain scission, creating short polymer links that can be washed or etched away with a solvent. Consequently, when positive-tone photoresist material is used, complementary structures of the interconnect structures 26 are exposed with the laser waist 52 within the volume of the photoresist material 50. Subsequently, the photoresist material is immersed in a solvent to remove the exposed areas and reveal the interconnect structures 26 based on the connectivity map 31.

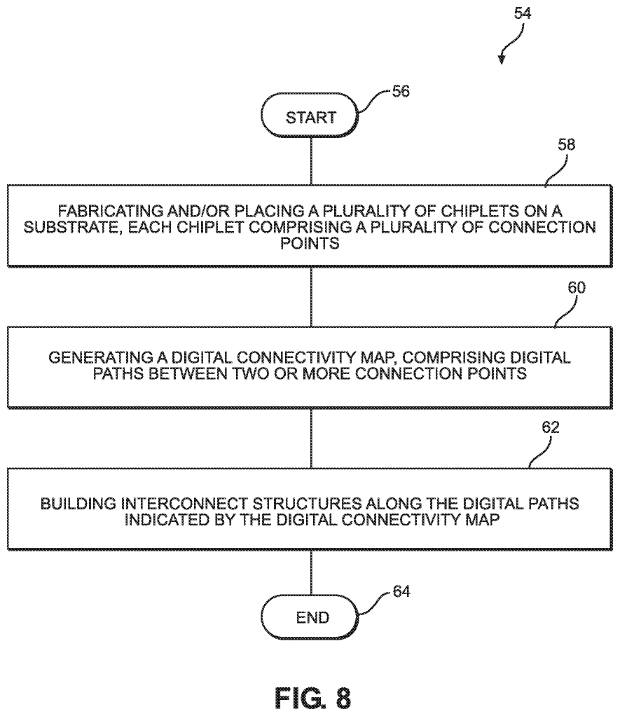

FIG. 8 illustrates a flowchart of a process 54 of manufacturing a multichip module (MCM) system according to an embodiment. The process 54 starts at the step 56. At step 58, a plurality of chiplets 18, 20 are placed and/or are fabricated on a substrate 12. Chiplets 18, 20 can include a plurality of connection points 22, 24. At step 60, a digital connectivity map 31 is generated based on desired connections in and between the chiplets 18, 20 and connection points 22, 24. one or more interconnect structures 26 can be fabricated or built between two or more of the plurality of the connection points 22, 24 of the chiplets 18, 20, communicatively coupling them, based on the digital connectivity map 31. For example, the digital connectivity map 31 can indicate a source connection point, a corresponding destination connection point, and a digital path routing the two connection points together. At step 62, various described methods can be used to build the interconnect structures 26 along the digital paths indicated in the digital connectivity map 31. The method ends at the step 64.

Example methods to build interconnect structures 26 can include: nonlinear optical lithography, photon-induced lithography, focused electron beam induced deposition (FEBID), focused ion beam, atomic optics, direct ink writing, electrohydrodynamic printing, local electrophoretic reduction, Meniscus-confined electroplating, electroplating of locally dispensed ions in liquid, laser-induced photoreduction, laser-assisted chemical vapor deposition (CVD), stimulated emission depletion (STED) lithography, laser induced forward transfer, and cryogenic FEBID or ion beam induced deposition.

For example, a negative-tone photoresist or thin film material doped with nano metallic particles can be deposited on the chiplets 18, 20 and a laser beam, electron beam, ion beam, and/or atom beam can be focused within the volume of the doped photoresist material to expose it along the digital path indicated by the connectivity map 31. Next, solvents can be used to remove the unexposed areas of the photoresist material and leave interconnect structures 26 in place, connecting the source and destination connection points. In other embodiments, a positive-tone photoresist material may be used where complementary structures of the interconnect structures 26 are exposed according to the connectivity map and washed away with a solvent to leave interconnect structures 26 in place. Example solvents include water, isopropyl alcohol, ethanol, dimethylformamide (DMF), tetrahydrofuran (THF), or others.

In some embodiments, the interconnect structures 26 can be deposited, without using a photoresist thin film layer, for example, by depositing precursor particles along the digital path using a focused beam of electron, ion or atoms. In other embodiments, an electrophoretic deposition technique can be used. In other embodiments, an electroplating technique can be used.

Multiple Substrate MCM Systems

Due to the ability of the described systems and methods of interconnect structures 26 to connect chiplets of varying heights and/or vertical or horizontal offsets, the interconnect structures 26 can be used to connect chiplets across multiple substrates. In some embodiments, the interconnect structures 26 can be used to connect chiplets across two or more substrates, where the substrates may also contain multiple systems and chiplets, such as their own MCMs. The substrates can be placed side-by-side, or in other arrangements and made to adhere to one another with adhesives, clamps or other mechanical or chemical fastening means. The interconnect structures 26 can be used to connect the chiplets and their connection points from one substrate to another.

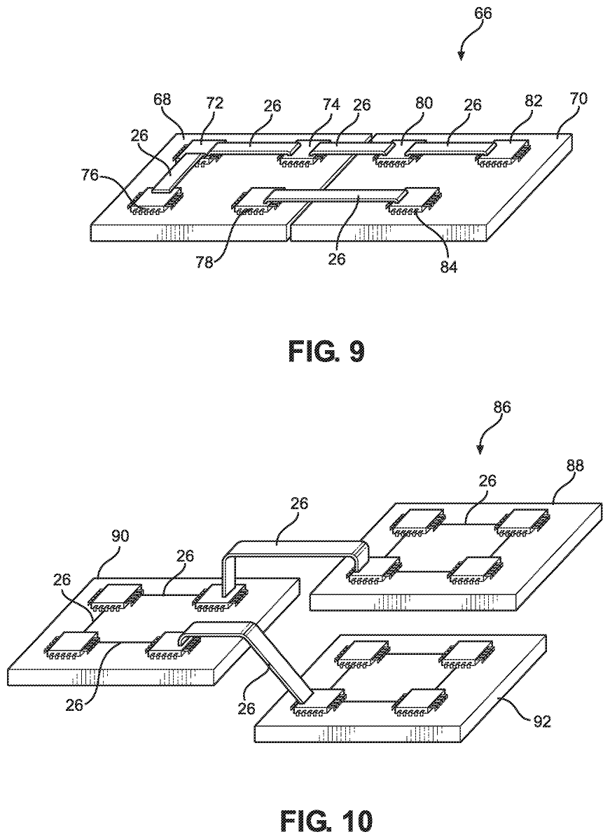

FIG. 9 illustrates a multi-substrate MCM system 66, where a side-by-side arrangement of substrates are used. Substrates 68 and 70 are placed adjacent and clamped, or otherwise secured to one another by mechanical or chemical means to reduce or minimize the movement of the substrates relative to one another. Substrates 68 and 70 can include a plurality of chiplets implementing various computing functionality. For example, substrate 68 can include the chiplets 72, 74, 76 and 78, and substrate 70 can include the chiplets 80, 82 and 84. However, the number of chiplets shown, are to provide examples and other numbers of chiplets on each substrate and/or more substrates can be used, employing the described systems and techniques. The chiplets 72-84 can be connected with the interconnect structures 26 as described above, allowing for the multi-substrate MCM system 66 to be scaled out to any desirable size system and computing power. In the example shown, the chiplets 74 and 78 on substrate 68 are connected to the chiplets 80 and 84 on substrate 70, respectively, using interconnect structures 26. The described multi-substrate systems, enable efficient manufacturing of massive computing systems by assembling pre-fabricated MCM substrates together based on desired specifications. The horizontal and side-by-side arrangement of the substrates can be used in various systems, including for example, data centers can be assembled on a single rack or on fewer racks using the described arrangement.

FIG. 10 illustrates an alternatively-arranged multi-substrate MCM system 86. Substrates can be stacked vertically, with or without overlapping regions, relative to one another and depending on desired connections between their internal chiplets. As an example, each substrate 88, 90 and 92 are a four-chiplet MCM system, where interconnect structures 26 are used to connect chiplets within each substrate and the chiplets between the different substrates. The described techniques for manufacturing the interconnect structures 26 enable building interconnect structures 26 between multiple substrates. Other methods of connecting chiplets, such as through-silicon-vias (TSVs) can also be used in combination with the interconnect structures 26.

As the physical size of the MCM systems increases, manufacturing chambers to build interconnect structures 26 can also increase in size. However, smaller-sized manufacturing chambers can also be utilized. For example, when chiplets across two substrates are to be connected, a manufacturing chamber building interconnect structures 26 can encapsulate the portions, where interconnect structures 26 are to be built, and build those structures, without impacting other regions. A variety of techniques can be used to isolate or encapsulate the portions of building the interconnect structures 26 from the environment and protect the volume inside the chamber and the area outside the chamber, depending on the chosen method of building the interconnect structures 26.

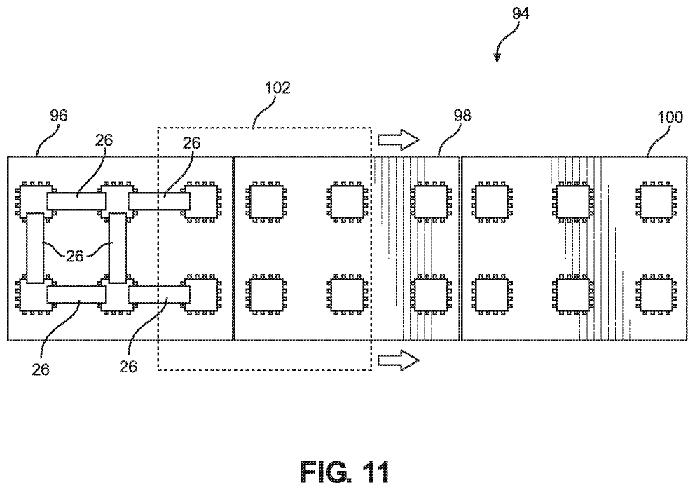

FIG. 11 illustrates a diagram of manufacturing interconnect structures 26 in a multi-substrate MCM system 94, with a chamber smaller than the substrates. The multi-substrate MCM system 94, includes six-chiplet substrates 96, 98 and 100. The manufacturing chamber 102, moves from left to right building interconnect structures 26 between the chiplets within a substrate and/or between the substrates. As described, a variety of methods can be used to isolate and/or encapsulate the portions that are to be exposed to manufacturing of the interconnect structures 26. These methods can include methods of creating vacuum using seals or gaskets, surrounding the manufacturing chamber 102.

What is claimed is:

1. A method of manufacturing a multichip system comprising:
fabricating and/or placing a plurality of chiplets on a substrate, each chiplet comprising a plurality of connection points; and
fabricating one or more interconnect structures between two or more of the plurality of the connection points of the chiplets, communicatively coupling two or more chiplets, wherein fabricating an interconnect structure comprises:
determining a source connection point;
determining a destination connection point;
generating a digital path between the source connection point and the destination connection point; and
building an interconnect structure along the digital path.

2. The method of claim 1, wherein the fabricating and/or placing of the plurality of the chiplets on the substrate is performed before fabricating the one or more interconnect structures.

3. The method of claim 1, wherein building the interconnect structure is performed by one or more of:
nonlinear optical lithography, photon-induced lithography, focused electron beam induced deposition (FEBID), focused ion beam, atomic optics, direct ink writing, electrohydrodynamic printing, local electrophoretic reduction, Meniscus-confined electroplating, electroplating of locally dispensed ions in liquid, laser-induced photoreduction, laser-assisted chemical vapor deposition (CVD), stimulated emission depletion (STED) lithography, laser induced forward transfer, and cryogenic FEBID or ion beam induced deposition.

4. The method of claim 3, wherein the nonlinear optical lithography comprises two or multi-photon polymerization lithography.

5. The method of claim 4, wherein the two or multi-photon polymerization lithography comprises polymerizing a photoresist material comprising nano metal particles.

6. The method of claim 4, further comprising coating the interconnect structure at least partially with a metal layer.

7. The method of claim 6, wherein coating comprises one or more of: electroless plating, electroplating, chemical vapor deposition (CVD), molecular beam epitaxy (MBE), atomic layer deposition (ALD), and physical vapor deposition (PVD).

8. The method of claim 1, wherein the one or more chiplets are misaligned in any direction in the three-dimensional space.

9. The method of claim 1, wherein the substrate contains topographical variations causing a misalignment in z-axis direction.

10. The method of claim 1, wherein the interconnect structures are driven by one or more of alternating current (AC)-coupled driving, capacitively-coupled AC interconnection, inductive coupling, galvanic connections, direct current (DC) or resistive connections, and serializer/de-serializer (SerDes).

11. The method of claim 1, wherein building the interconnect structure comprises focusing a light beam, an electron beam, an ion beam, and/or an atom beam along the digital path.

12. The method of claim 1, wherein building the interconnect structure comprises depositing electrically conductive material along the digital path.

13. The method of claim 1, wherein building the interconnect structure comprises coating the interconnect structure with electrically conductive material.

14. A multichip module system comprising:
a plurality of chiplets on a substrate, each chiplet comprising a plurality of connection points; and
one or more interconnect structures fabricated between two or more of the plurality of the connection points of the chiplets, communicatively coupling the two or more chiplets, wherein the interconnect structures are fabricated in photoresist material, and/or are deposited between the connection points by focusing a light beam, an electron beam, an ion beam, and/or an atom beam along a digital path indicating electrical connection between the connection points.

15. The system of claim 14, wherein the chiplets are placed on the substrate before the interconnect structures are fabricated between the two or more of the plurality of the connection points.

16. The system of claim 14, wherein the interconnect structures are fabricated by one or more of:
nonlinear optical lithography, photon-induced lithography, focused electron beam induced deposition (FEBID), focused ion beam, atomic optics, direct ink writing, electrohydrodynamic printing, local electrophoretic reduction, Meniscus-confined electroplating, electroplating of locally dispensed ions in liquid, laser-induced photoreduction, laser-assisted chemical vapor deposition (CVD), stimulated emission depletion (STED) lithography, laser induced forward transfer, and cryogenic FEBID or ion beam induced deposition.

17. The system of claim 16, wherein nonlinear optical lithography comprises two or multi-photon polymerization lithography.

18. The system of claim 17, wherein the two or multi-photon polymerization lithography comprises polymerizing a photoresist material comprising nano metal particles.

19. The system of claim 16, wherein the interconnect structures are coated at least partially with a metal layer, wherein the coating comprises one or more of: electroless plating, electroplating, chemical vapor deposition (CVD), molecular beam epitaxy (MBE), atomic layer deposition (ALD), and physical vapor deposition (PVD).

20. The system of claim 14, wherein the interconnect structures are driven by one or more of alternating current (AC)-coupled driving, capacitively-coupled AC interconnection, inductive coupling, galvanic connections, direct current (DC) or resistive connections, and serializer/de-serializer (SerDes).
